(19) United States
(12) Patent Application Publication
(10) Pub. No.: US 2014/0036442 A1
(43) Pub. Date: Feb. 6, 2014

(54) OUTDOOR STACKABLE TELECOMMUNICATIONS EQUIPMENT CABINET FAMILY WITH FLEXIBLE THERMAL AND INTERFACE MANAGEMENT AND METHOD OF DEPLOYING THE SAME

(71) Applicants: Peter Giannoglou, Towaco, NJ (US); Allen Schultz, Gillette, NJ (US); Jochen Seiss, Sachsenheim (DE)

(72) Inventors: Peter Giannoglou, Towaco, NJ (US); Allen Schultz, Gillette, NJ (US); Jochen Seiss, Sachsenheim (DE)

(73) Assignees: Alcatel-Lucent Deutschland AG, Stuttgart (DE); Alcatel-Lucent USA, Inc., Murray Hill, NJ (US)

(21) Appl. No.: 13/562,986

(22) Filed: Jul. 31, 2012

(51) Int. Cl. H05K 7/20; H05K 13/00

(52) U.S. Cl. 361/695; 29/592.1

(57) ABSTRACT

An outdoor stackable telecommunications equipment cabinet family and a method of deploying an outdoor telecommunications equipment cabinet. In one embodiment, the family includes: (1) a plurality of selectable cabinet modules and (2) a plurality of selectable plinth modules, at least one of the plurality of selectable cabinet modules and one of the plurality of selectable plinth modules configured to be selected and stacked to form an outdoor telecommunications equipment cabinet that includes an air filter and at least one fan.

### TECHNICAL FIELD

This application is directed, in general, to modular electronic chassis and, more specifically, to a outdoor modular electronic chassis.

### BACKGROUND

Telecommunications equipment (such as wireless base stations) needs to be located outdoors, because they are widely geographically distributed where suitable, environmentally controlled buildings are rarely available. Electrical codes and equipment manufacturers' operating specifications require equipment located outdoors to be housed in an outdoor-rated cabinet capable of maintaining an internal environment equivalent to an environmentally controlled building.

Several factors need to be taken into consideration in designing an appropriate outdoor-rated cabinet. First, it is important to identify which equipment needs to be housed inside the cabinet to ensure that the cabinet has the appropriate features (e.g., radio-frequency, or RF, equipment needing a high cooling capacity, digital baseband equipment requiring especially clean air or batteries needing adequate venting for the hydrogen gas they produce). The common practice in the industry is to have somewhat specialized cabinets with the associated restrictions. For example, an equipment supplier may offer a cabinet that is designed to house RF equipment, but that same cabinet may not be suitable for digital baseband equipment due to environmental conditions (e.g., the air may be clean enough for RF equipment, but not clean enough for digital equipment). Complicating matters is that different sites often require different interfaces to the outside world (e.g., cable egress styles, different locations of interfaces on different surfaces). As a result, many different custom cabinet configurations are required to satisfy the type and amount of the equipment and the particular environment each site presents.

### SUMMARY

One aspect provides an outdoor stackable telecommunications equipment cabinet family. In one embodiment, the family includes: (1) a plurality of selectable cabinet modules and (2) a plurality of selectable plinth modules, at least one of the plurality of selectable cabinet modules and one of the plurality of selectable plinth modules configured to be selected and stacked to form an outdoor telecommunications equipment cabinet that includes an air filter and at least one fan.

In another embodiment, the family includes: (1) a plurality of selectable cabinet modules, (2) a plurality of selectable plinth modules and (3) a plurality of selectable interface plates each having at least one interface aperture, at least one of the plurality of selectable cabinet modules and one of the plurality of selectable plinth modules configured to be selected and stacked and one of the plurality of selectable interface plates coupled to the one of the plurality of selectable plinth modules to form an outdoor telecommunications equipment cabinet that includes shutters, an air filter and at least one fan.

Another aspect provides a method of deploying an outdoor telecommunications equipment cabinet. In one embodiment, the method includes: (1) determining a configuration for the cabinet based on telecommunications equipment to be located at the particular site, (2) determining a configuration and size of a plinth module based on interfaces required at the particular site, (3) selecting at least one cabinet module from a plurality of selectable cabinet modules and one plinth module from a plurality of selectable plinth modules, the plurality of selectable cabinet modules and the plurality of selectable plinth modules being part of an outdoor stackable telecommunications equipment cabinet family and (4) assembling the telecommunications equipment cabinet from the selected cabinet and plinth modules.

### BRIEF DESCRIPTION

Reference is now made to the following descriptions taken in conjunction with the accompanying drawings, in which:

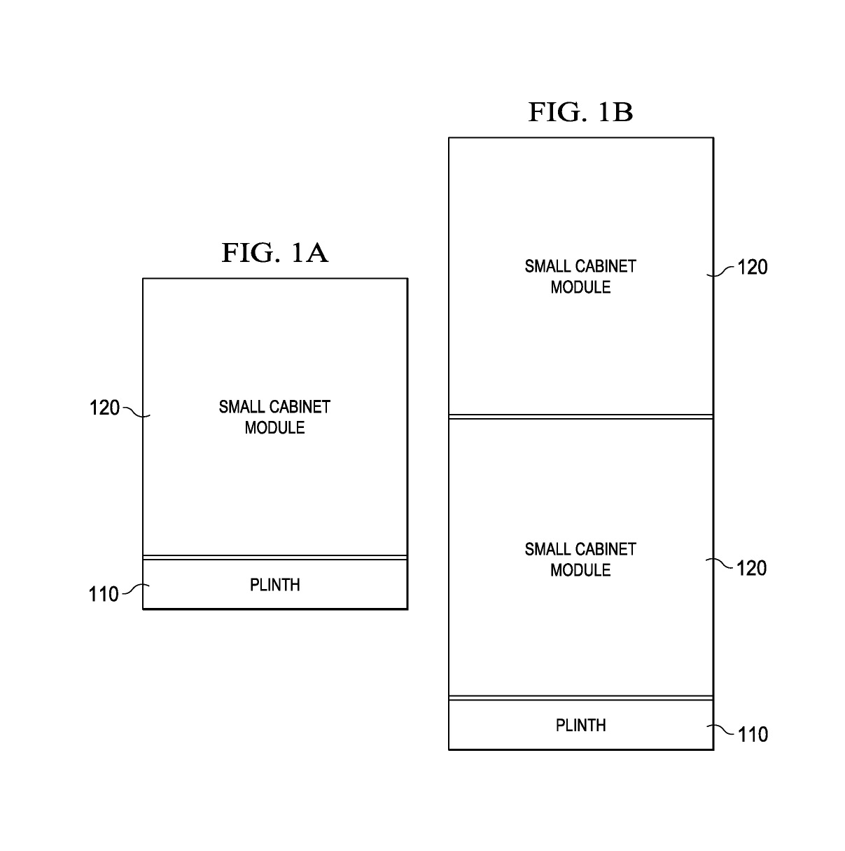

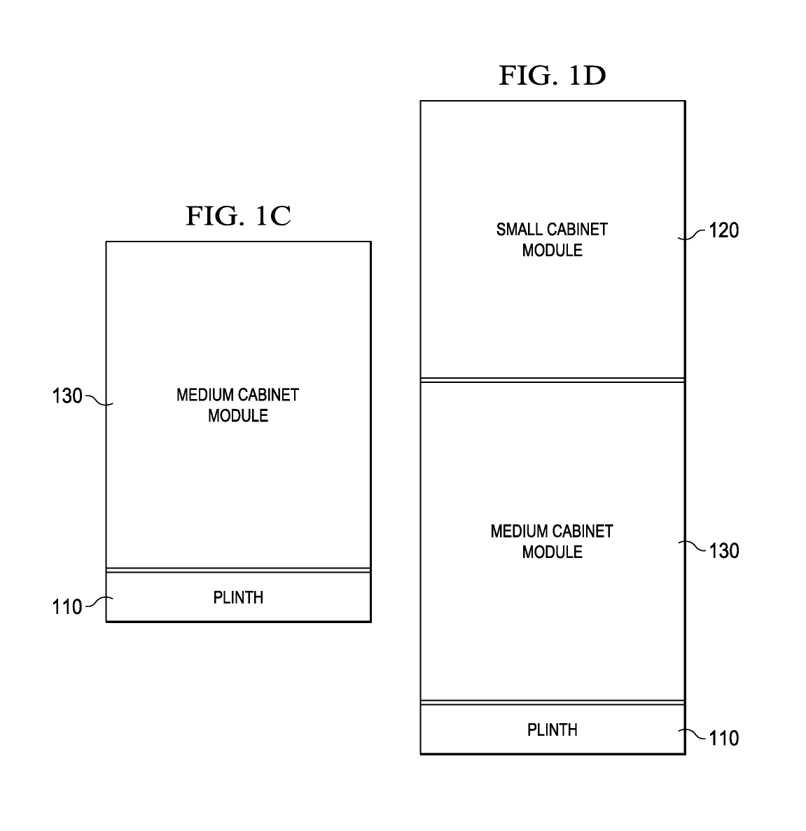

FIGS. 1A-1D are high-level block diagrams of four alternative stacks of one embodiment of a family of stackable outdoor telecommunications equipment modules;

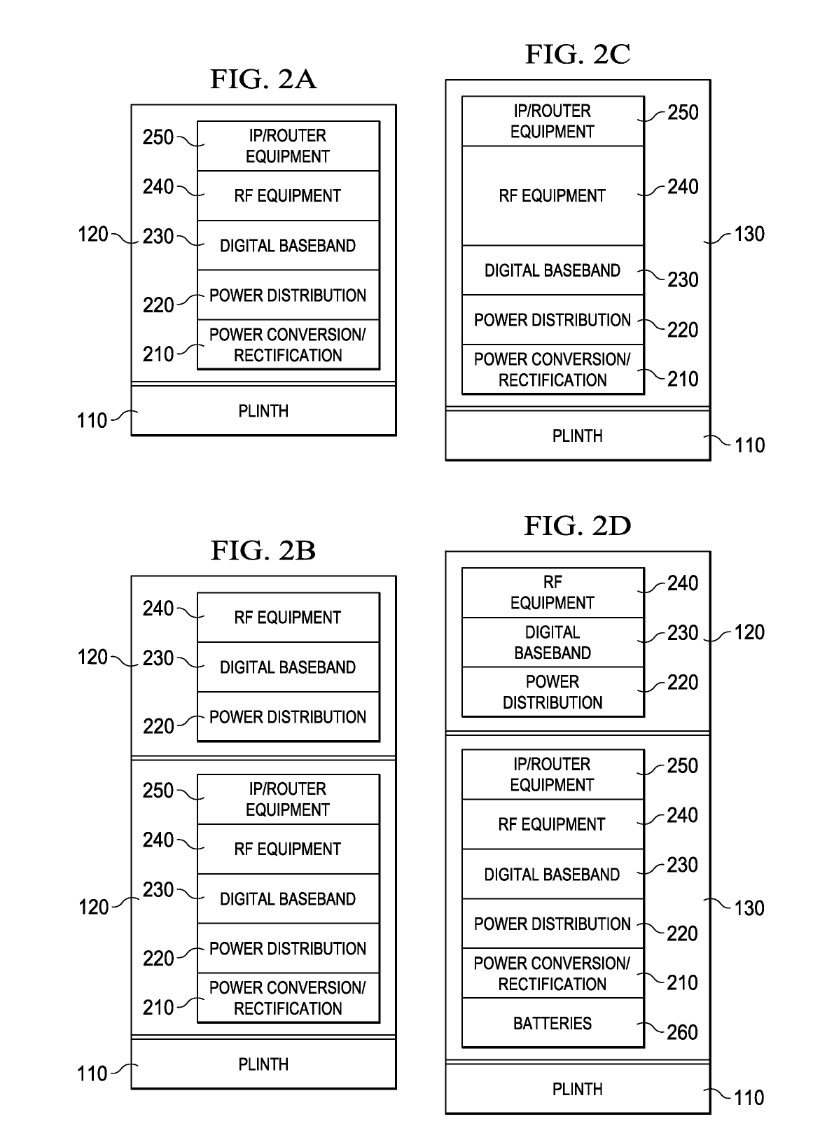

FIGS. 2A-2D are block diagrams of hardware element arrangements within the alternative stacks of FIGS. 1A-1D;

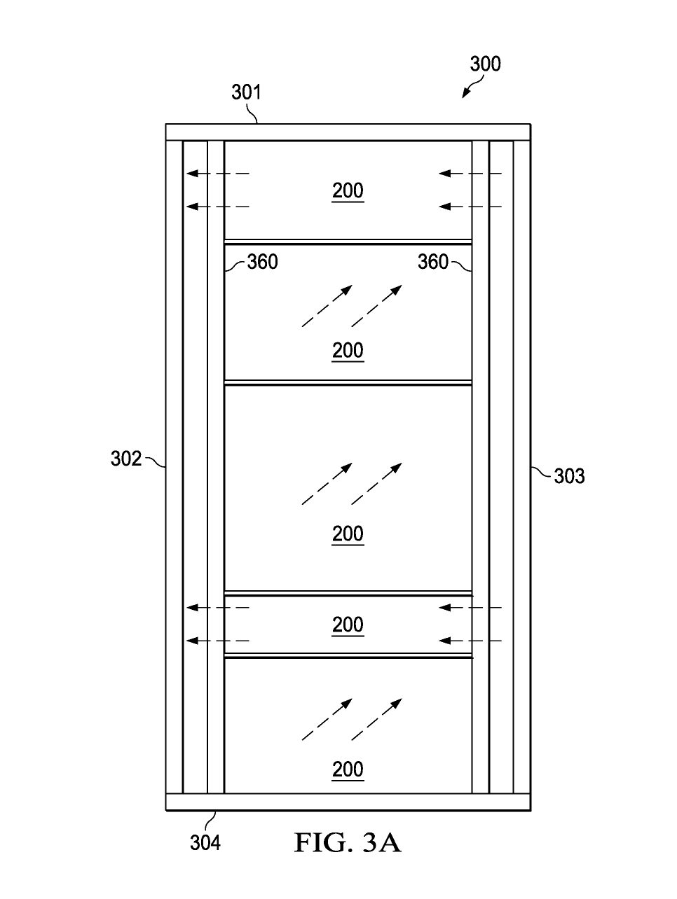

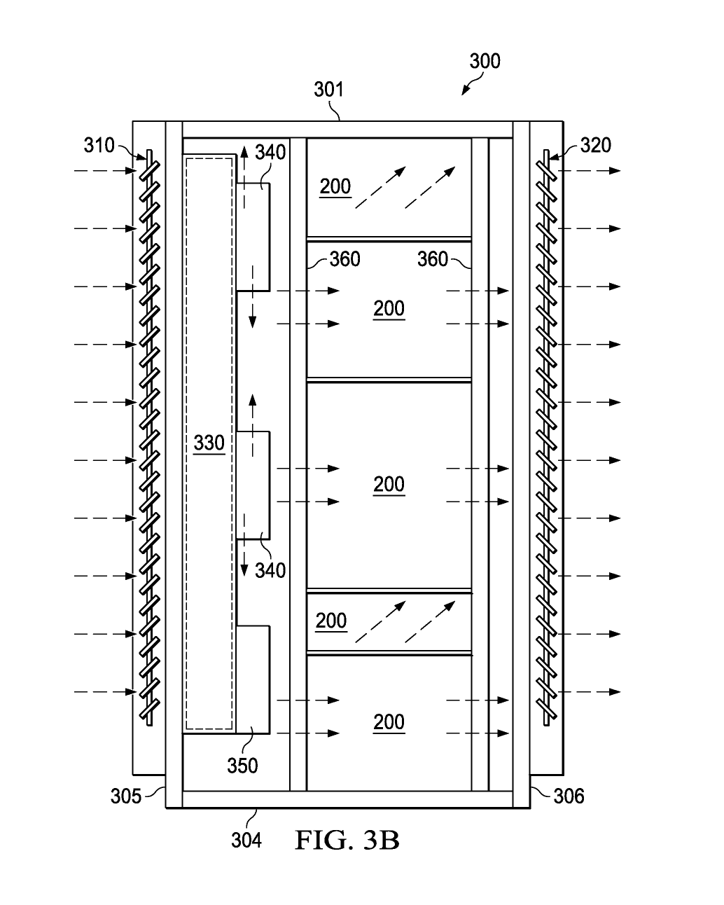

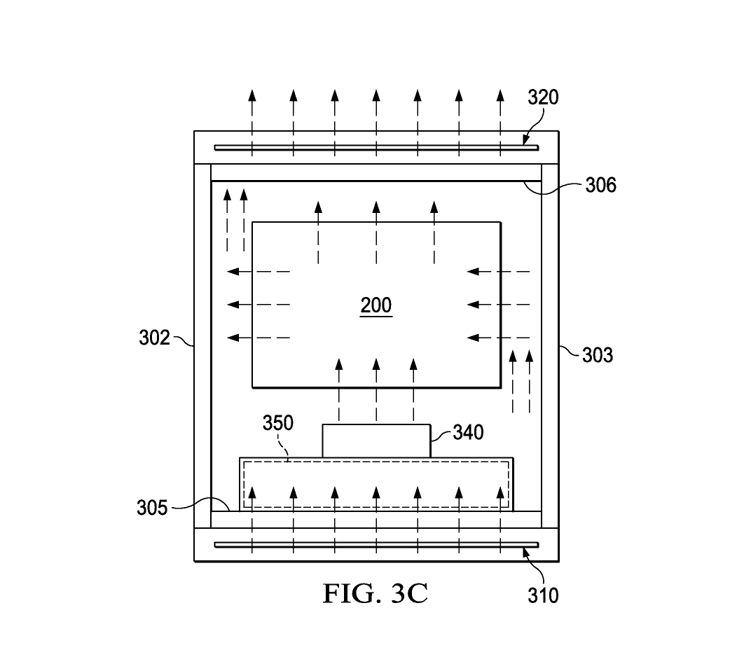

FIGS. 3A-3C are respective front elevational, left-side elevational and top-side plan views of one embodiment of an outdoor telecommunications equipment cabinet showing airflow through the cabinet and hardware elements therein;

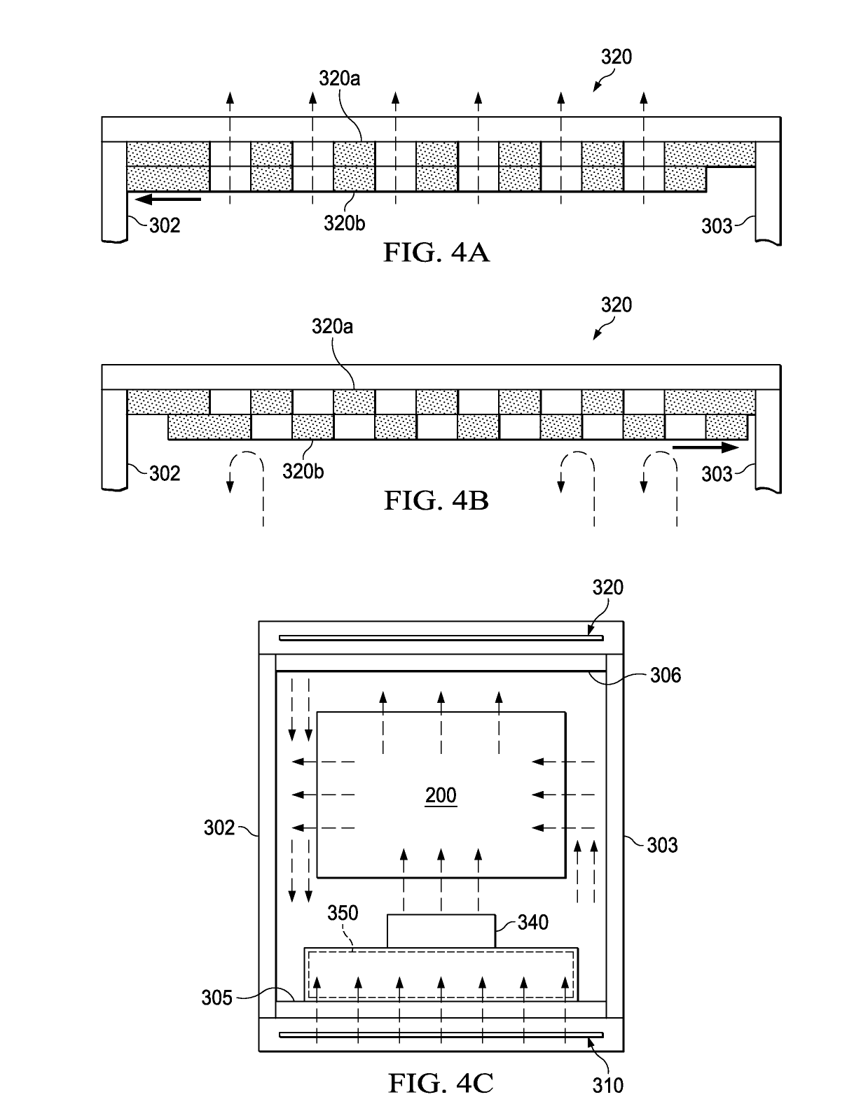

FIGS. 4A and 4B respectively illustrate open and closed positions of one embodiment of a shutter of one embodiment of an outdoor telecommunications equipment cabinet;

FIG. 4C is a top-side plan view of one embodiment of an outdoor telecommunications equipment cabinet showing airflow through the cabinet and hardware elements therein when the shutter of FIGS. 4A and 4B is in the fully closed position;

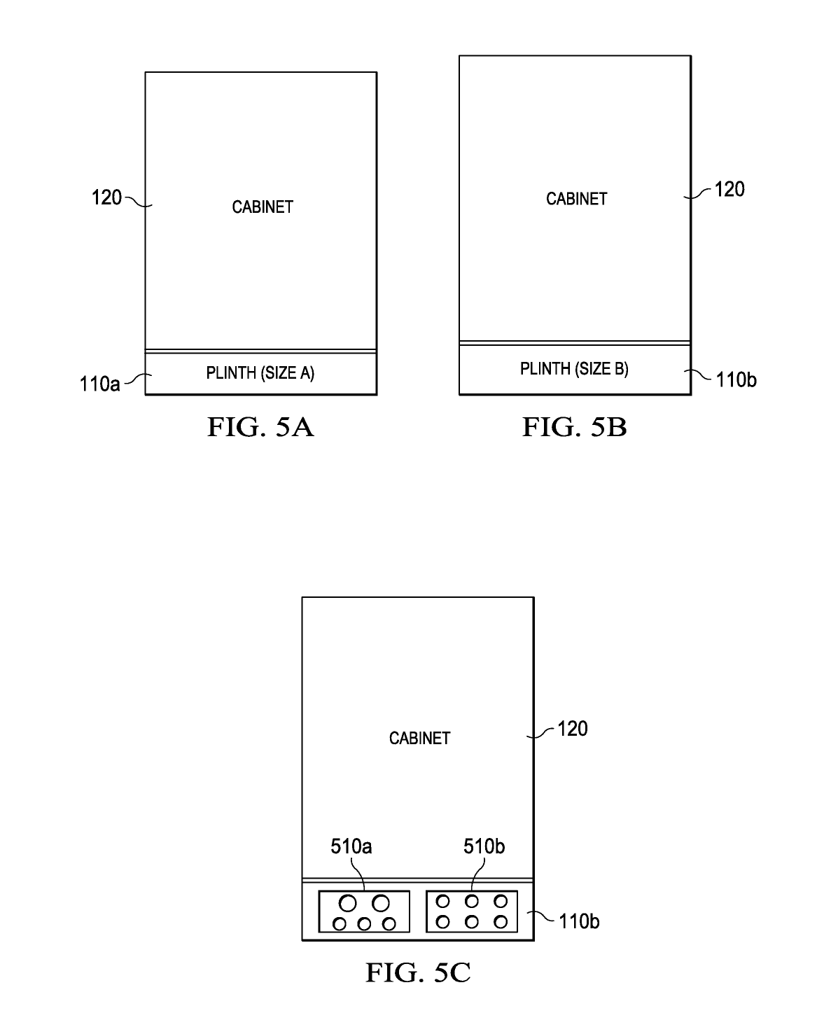

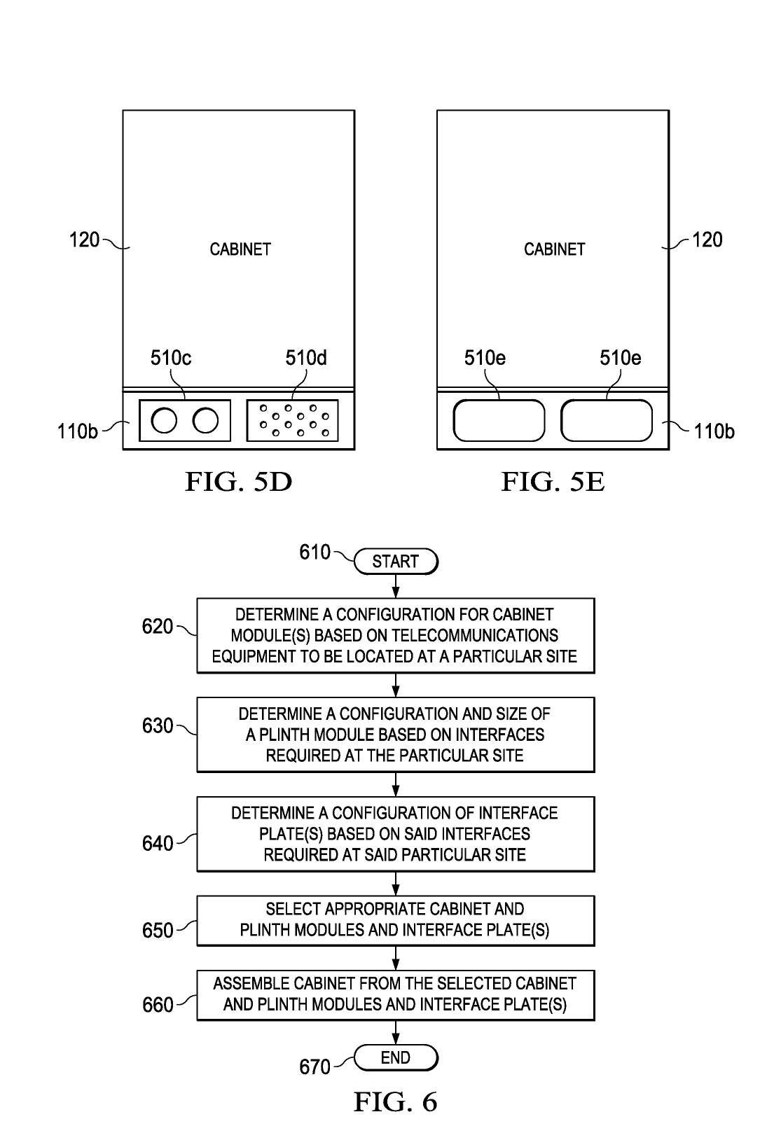

FIGS. 5A-5B shows alternative plinths for one embodiment of a stackable outdoor telecommunications equipment cabinet;

FIGS. 5C-5E show alternative embodiments of interface configurations for the plinth of FIG. 5B; and

FIG. 6 is a flow diagram of one embodiment of a method of deploying an outdoor telecommunications equipment cabinet.

### DETAILED DESCRIPTION

As stated above, many different custom cabinet configurations are required to satisfy the type and amount of the telecommunications equipment and the particular environment each telecommunications equipment site presents. Accordingly, most telecommunications equipment suppliers make specific outdoor cabinets to meet specific needs, resulting in a panoply of cabinet sizes and configurations customized for a specific collection of hardware elements. (The terms “hardware elements” and “telecommunications equipment” are used synonymously herein.)

As a result, one needs to know beforehand what equipment configurations and interfaces are required at a particular site not only initially but in the future before choosing a conventional cabinet. Complicating the job of selecting a cabinet is the fact that most commercially available cabinets do not allow the needed equipment to be mounted anywhere inside the cabinet, but rather require certain hardware elements to be mounted in certain positions. For example, RF equipments must be in a designated position, and digital baseband or supporting equipment (such as rectifiers) must be confined to certain sections or areas of the cabinet. In cases in which one or more backup batteries are necessary, conventional cabinets frequently limit the size or locations within the cabinet where the one or more backup batteries can be placed to ensure proper hydrogen gas venting.

It is realized herein that a single cabinet family that can adequately address the need for customization would be far more advantageous than the conventional proliferation of custom cabinets. Various embodiments of the cabinet family have one or more of the following features:

(A) a range of overall cabinet size achieved through modularity, i.e., cabinet modules that can be stacked to create the desired cabinet size;

(B) a relatively small number of separate cabinet modules to avoid cost and complexity (e.g., two cabinet modules and two plinth modules in some embodiments);

(C) cabinet modules that allow a variety of hardware to be installed inside, including digital baseband equipment, high power RF equipment, power conversion and rectification equipment and one or more backup batteries;

(D) a cabinet that provides a high-capacity thermal control environment configured to support a variety of telecommunications equipment styles (e.g., modules cooled using longitudinal airflow or modules cooled using lateral airflow) over the full range of the external environment (e.g., dust, extreme cold, extreme heat and heavy, wind-driven rain);

(E) a cabinet that creates a thermal environment in which the temperature rise inside the cabinet is held relatively low (compared to the outside ambient environment) to allow temperature-sensitive equipment (e.g., RF modules and one or more backup batteries) to operate without substantial impairment, reduced reliability or life; and

(F) a cabinet that accommodates a wide range of interfaces thereby to make the cabinet compatible with common practices in different regions of the world (e.g., metal conduit in the USA and cable troughs in Europe), different types and quantities of interfaces (e.g., power, network connections, fiber links and RF antennas) and different customer preferences for interface entry (e.g., rear entry, left-side entry and right-side entry).

It is realized herein that, with some or all of the above-described features, members of a single cabinet family can be combined in various ways to provide a spectrum of outdoor cabinet configurations, reducing, and perhaps eliminating, the need to create custom, perhaps site-specific, cabinet designs. The resulting outdoor telecommunications equipment cabinet family yields a drastic reduction and simplification in product portfolio, a significant reduction in operating costs and better cabinet inventory management.

Various embodiments to be illustrated and described introduces a modular and generic cabinet family that provides such equipment space as needed and allows all common types of telecommunications equipment (or “hardware elements”) to occupy the space. Certain embodiments of the cabinet family provide an equipment space (or spaces, when combined through stacking) provides a relatively high thermal capacity, a relatively clean air environment, a relatively low temperature rise above the external ambient temperature, sufficient venting for hydrogen, and proper protection against rain and water intrusion. In addition, the cabinet family features a flexible plinth module approach that allows interfaces to be customized in the plinth module without affecting the basic cabinet design. As a result, one cabinet family is sufficient to meet all foreseeable needs of the telecommunications service providers.

Having described features and some embodiments of a family of FIGS. 1A-1D are high-level block diagrams of four alternative stacks of one embodiment of stackable outdoor telecommunications equipment cabinet modules. FIG. 1A shows a first alternative stack including a plinth module 110 and a small cabinet module 120 stacked on the plinth module 110. The first alternative stack may be suitable for a typical small telecommunications equipment site. FIG. 1B shows a second alternative stack including the plinth module 110 and two small cabinet modules 120 stacked on the plinth module 110. FIG. 1C shows a third alternative stack including the plinth module 110 and a medium cabinet module 130 stacked on the plinth module 110. FIG. 1D shows a fourth alternative stack including the plinth module 110, a small cabinet module 120 stacked on the plinth module 110 and a medium cabinet modules 120 stacked on the small cabinet module 120. The fourth alternative stack may be suitable for a typical large telecommunications equipment site, perhaps one requiring one or more backup batteries.

A host of other alternative stacks are possible, including stacks using more than one or two cabinet modules, stacks using cabinet modules that are smaller than the small cabinet module 120, between the size of the small cabinet module 120 and the medium cabinet module 130 or larger than the medium cabinet module 130 and stacks in which larger modules are stacked over smaller modules. As will be seen below, the size of the plinth module 110 can also vary.

It is apparent that the above embodiments, capable of yielding many different alternative stacks, provide a range of overall cabinet size achieved through modularity, i.e., cabinet modules that can be stacked to create the desired cabinet size and further that the relatively small number (i.e., only two) separate cabinet modules avoid cost and complexity, thus meeting at least features (A) and (B) described above.

FIGS. 2A-2D are block diagrams of hardware element arrangements within the alternative stacks of FIGS. 1A-1D. A first alternative stack of FIG. 2A corresponds to the first alternative stack of FIG. 1A. The small cabinet module 120 houses relatively small, typically lower-power, hardware elements such as power conversion/rectification equipment 210, power distribution equipment 220, digital baseband equipment 230, RF equipment 240 and Internet Protocol (IP)/router equipment 250. A second alternative stack of FIG. 2B corresponds to the second alternative stack of FIG. 1B. The lower of the two small cabinet modules 120 houses relatively small, typically lower-power, hardware elements such as power conversion/rectification equipment 210, power distribution equipment 220, digital baseband equipment 230, RF equipment 240 and IP/router equipment 250. The upper of the two small cabinet modules 120 houses hardware elements such as further power distribution equipment 220, further digital baseband equipment 230 and further RF equipment 240.

A third alternative stack of FIG. 2C corresponds to the third alternative stack of FIG. 1C. The medium cabinet module 130 houses relatively large, typically higher-power, hardware elements such as power conversion/rectification equipment 210, power distribution equipment 220, digital baseband equipment 230, RF equipment 240 and IP/router equipment 250. A fourth alternative stack of FIG. 2D corresponds to the fourth alternative stack of FIG. 1D. The lower of the two medium cabinet modules 130 houses relatively large, typically higher-power, hardware elements such as power conversion/rectification equipment 210, power distribution equipment 220, digital baseband equipment 230, RF equipment 240, IP/router equipment 250 and one or more backup batteries 260. The upper of the two medium cabinet modules 130 houses hardware elements such as further power distribution equipment 220, further digital baseband equipment 230 and further RF equipment 240.

It is apparent that the above embodiments, capable of yielding many different alternative stacks, allow a variety of hardware to be installed inside, including digital baseband equipment, high power RF equipment, power conversion and rectification equipment and one or more backup batteries, meeting at least feature (C) described above.

FIGS. 3A-3C are respective front elevational, left-side elevational and top-side plan views of one embodiment of an outdoor telecommunications equipment cabinet 300 showing airflow through the cabinet and hardware elements therein. Referring specifically to FIG. 3A, the cabinet 300 has a generally planar top panel 301, a generally planar left-side panel 302, a generally planar right-side panel 303 and a generally planar bottom panel 304. The left-side panel 302, right-side panel 303 and bottom panel 304 are associated with a single cabinet module or a stack of plural cabinet modules, depending upon how many cabinet modules are employed to form the cabinet. In the illustrated embodiment, the top panel 301 is integral with the cabinet module beneath it. In an alternative embodiment, the top panel 301 is a separate part joined to the cabinet module beneath it when the modules of the cabinet 300 are assembled together.

In the illustrated embodiment, the top panel 301, left-side panel 302, right-side panel 303 and bottom panel 304 are formed of metal, perhaps steel, sheets. In the illustrated embodiment, the top panel 301, left-side panel 302, right-side panel 303 and bottom panel 304 are substantially continuous (solid) sheets thereby such that they are impervious to rain and dust.

Referring specifically to FIG. 3B, the cabinet further has a rear panel 305 and a front panel 306. In the illustrated embodiment, both the rear panel 305 and front panel 306 are hingedly mounted to the left-side panel 302 and the right-side panel 303 to form rear and front cabinet doors. In an alternative embodiment, only one of the rear panel 305 and front panel 306 is hingedly mounted to the left-side panel 302 and the right-side panel 303; the other one of the rear panel 305 and front panel 306 is affixed to the left-side panel 302 and the right-side panel 303 to yield a cabinet having a single door. In the illustrated embodiment, locks or latches (not shown) are provided to secure the rear panel 305 and front panel 306 as against inadvertent or unauthorized opening.

The cabinet 300 further contains a first shutter 310 associated with the rear panel 305 and a second shutter 320 associated with the front panel 306. Accordingly, in the illustrated embodiment, the rear panel 305 and the front panel 306 are perforated, slotted or otherwise provided with one or more passages (not shown) configured to admit air into, or accept air from, the first and second shutters 310, 320. In one embodiment, each of the rear panel 305 and the front panel 306 is provided with a relatively large aperture that spans much of the area of the first shutter 310 and the second shutter 320.

The cabinet 300 further includes an air filter 330, a fan 340 and a heater 350. In a preferred embodiment, the heater 350 includes a fan. The specific embodiment of FIGS. 3A-3C includes two fans 340. Other embodiments have only one fan 340. Still other embodiments have multiple heaters 350.

With concurrent reference to FIGS. 3A and 3B, hardware element supports 360 are located within the cabinet 300 and are configured to support hardware elements 200 (e.g., the telecommunications equipment described above, perhaps particularly in conjunction with FIGS. 2A-2D).

In the illustrated embodiment, the hardware element supports 360 are substantially vertical members with periodic apertures or other registration features (not shown), such as tabs or brackets configured to mount the hardware elements 200 at predetermined levels thereof, like a rack. Also in the illustrated embodiment, the hardware element supports 360 are substantially spaced apart from one another to allow substantial airflow among them and the hardware elements 200 mounted on them. In the illustrated embodiment, the hardware element supports 360 are spaced apart to allow both substantial longitudinal airflow and substantial lateral airflow. In alternative embodiments, cross-members or other structural supports (not shown) joining the hardware element supports 360 may impede substantial longitudinal airflow or substantial lateral airflow at one or more locations along their height, depending upon where the hardware elements 200 are mounted. While not favored, this embodiment falls within the broad scope of the invention.

With reference to FIGS. 3A-3C, unreferenced arrows show example air movement through the cabinet 300 in the presence of example hardware elements and with the fans 340 and/or the fan associated with the heater 350 activated. It is readily apparent that air moves into the cabinet 300 through the shutter 310 and the air filter 340, flows freely through the cabinet 300 in various longitudinal and lateral directions among and across the hardware elements 200 and then exits the cabinet 300 through the shutter 320 as shown. The movement of the air through both the shutters 310, 320 may be regarded as a fully-ventilated mode of operation, which may be particularly advantageous during times of high ambient temperature or when the hardware elements are dissipating relatively large quantities of heat.

FIGS. 4A and 4B respectively illustrate open and closed positions of one embodiment of a shutter (e.g., the shutter 320 of FIGS. 3A-3C) of one embodiment of an outdoor telecommunications equipment cabinet (e.g., the cabinet 300 of FIGS. 3A-3C). In the embodiment of FIGS. 4A and 4B, the shutter 320 includes two shutter portions 320a, 320b that are translatable with respect to one another to open, partially close or fully close the shutter 320. An actuator (not shown) may be employed to perform the translation. As those skilled in the pertinent art will understand, the shutter 320 (or the shutter 310 of FIGS. 3A-3C) may be employed fully to admit outside air into the cabinet 300 or restrict or prevent such air from entering the cabinet 300 depending upon ambient conditions, such as temperature, humidity and rain or dust content. Although not shown, the cabinet 300 may further be fitted with an air conditioner, allowing further control of the environment within the cabinet 300.

FIG. 4C is a top-side plan view of one embodiment of an outdoor telecommunications equipment cabinet showing airflow through the cabinet and hardware elements therein when a shutter 320 of FIGS. 4A and 4B is in the fully closed position. Unreferenced arrows show example air movement through the cabinet 300 in the presence of example hardware elements and with the fans 340 and/or heater 350 activated. It is readily apparent that air moves into the cabinet 300 through the shutter 310 and the air filter 340, flows freely through the cabinet 300 in various longitudinal and lateral directions among and across the hardware elements 200, but then circulates back within the cabinet 300 instead of exiting the cabinet 300 through the shutter 320. The movement of the air through one, but not both, of the shutters 310, 320 may be regarded as a partially-ventilated mode of operation, which may be particularly advantageous during times of moderate ambient temperature or when the hardware elements are dissipating nominal quantities of heat.

Of course, both of the shutters 310, 320 may be fully closed, wherein the air circulates within the cabinet 300 without exiting or the admission of outside air. The movement of the air in the cabinet 300 when both of the shutters 310, 320 are fully closed may be regarded as an internally-ventilated mode of operation, which may be particularly advantageous during times of low ambient temperature, during rain or dust conditions or when the hardware elements are dissipating relatively low quantities of heat. The heater 350 of FIGS. 3A-3C may also be activated to provide additional heat during times of particularly low ambient temperatures.

It is apparent that the above embodiments, capable of providing a high-capacity thermal control environment configured to support a variety of telecommunications equipment styles (e.g., modules cooled using longitudinal airflow or modules cooled using lateral airflow) over the full range of the external environment (e.g., dust, extreme cold, extreme heat and heavy, wind-driven rain) and further capable of creating a thermal environment in which the temperature rise inside the cabinet is held relatively low (compared to the outside ambient environment) to allow temperature-sensitive equipment (e.g., RF modules and one or more backup batteries) to operate without substantial impairment, reduced reliability or life, meet at least features (D) and (E) described above.

FIGS. 5A-5B shows alternative plinth modules for one embodiment of a stackable outdoor telecommunications equipment cabinet. The plinth module generally serves as a pedestal to raise the cabinet modules off the ground and to allow for a variety of interfaces to be accommodated. In many cases, a site may not be set up to be compatible with the cabinet, but with a plinth module for the interfaces, such incompatibilities can be reconciled.

FIG. 5A shows a first alternative plinth module 110a having a first predetermined height. FIG. 5B shows a second alternative plinth module 110b having a second predetermined height that exceeds the first predetermined height. FIGS. 5A and 5B demonstrate that the outdoor stackable telecommunications equipment cabinet family disclosed herein may advantageously include plinth modules of differing height.

FIGS. 5C-5E show alternative embodiments of interface configurations for the plinth module 110b of FIG. 5B. A first alternative embodiment, shown in FIG. 5C, includes first and second interface plates 510a, 510b mounted on a rear surface of the plinth module 110b and having interface apertures of various diameter, ostensibly to receive conduits of various size. A second alternative embodiment, shown in FIG. 5D, includes third and fourth interface plates 510c, 510d on a side surface of the plinth module 110b and having interface apertures of various diameter, ostensibly to receive conduits of various size. A third alternative embodiment, shown in FIG. 5E, includes two instances of a fifth interface plate 510e on the rear surface of the plinth module 110b and having wide, generally rectangular apertures, ostensibly to receive cable troughs.

It is apparent that the above embodiments, capable of accommodating a wide range of interfaces thereby to make the cabinet compatible with common practices in different regions of the world (e.g., metal conduit in the USA and cable troughs in Europe), different types and quantities of interfaces (e.g., power, network connections, fiber links and RF antennas) and different customer preferences (e.g., rear entry, left side entry and right side entry), meet at least feature (F) described above.

FIG. 6 is a flow diagram of one embodiment of a method of deploying an outdoor telecommunications equipment cabinet. The method begins in a step 610, wherein it is desired to create a cabinet for a particular telecommunications equipment site using modules selected from an outdoor stackable telecommunications equipment cabinet family. In a step 620, a configuration for one or more cabinet modules is determined based on the telecommunications equipment to be located at the particular site. For example, the equipment to be located at the particular site may be such that a cabinet assembled from a medium cabinet module and a small cabinet module.

In a step 630, a configuration and size of a plinth module are determined based on the interfaces required at the particular site. In a step 640, a configuration of at least one interface plate is determined based on the interfaces required at the particular site. For example, the interfaces may indicate that a plinth module of a second predetermined height and having a rear entry for conduits should be selected. The interfaces may also indicated that multiple interface plates having interface apertures of various diameter should be selected. Accordingly, a higher plinth module having first and second interface plates mounted on a rear surface thereof and having interface apertures of various diameter for conduits of various size is selected. In a step 650, the appropriate cabinet and plinth modules and at least one interface plate are selected. In a step 660, the cabinet is assembled from the selected cabinet and plinth modules and at least one interface plate. The method ends in an end step 670.

Those skilled in the art to which this application relates will appreciate that other and further additions, deletions, substitutions and modifications may be made to the described embodiments.

What is claimed is:

1. An outdoor stackable telecommunications equipment cabinet family, comprising:
a plurality of selectable cabinet modules; and
a plurality of selectable plinth modules, at least one of said plurality of selectable cabinet modules and one of said plurality of selectable plinth modules configured to be selected and stacked to form an outdoor telecommunications equipment cabinet that includes an air filter and at least one fan.

2. The family as recited in claim 1 wherein said telecommunications equipment cabinet includes shutters.

3. The family as recited in claim 1 wherein said telecommunications equipment cabinet contains hardware element supports having registration features.

4. The family as recited in claim 3 wherein said hardware element supports are spaced apart to allow both substantial longitudinal airflow and substantial lateral airflow.

5. The family as recited in claim 1 wherein said telecommunications equipment cabinet includes a heater.

6. The family as recited in claim 1 further comprising a plurality of selectable interface plates each having at least one interface aperture, at least one of said plurality of selectable interface plates configured to be selected and coupled to said one of said plurality of plinth modules.

7. The family as recited in claim 1 wherein said telecommunications equipment is selected from the group consisting of:
power conversion/rectification equipment,
power distribution equipment,
digital baseband equipment,
radio frequency equipment;
Internet Protocol/router equipment, and
a backup battery.

8. A method of deploying an outdoor telecommunications equipment cabinet, comprising:
determining a configuration for at least one cabinet module based on telecommunications equipment to be located at said particular site;
determining a configuration and size of a plinth module based on interfaces required at said particular site;
selecting said at least one cabinet module from a plurality of selectable cabinet modules and said plinth module from a plurality of selectable plinth modules, said plurality of selectable cabinet modules and said plurality of selectable plinth modules being part of an outdoor stackable telecommunications equipment cabinet family; and
assembling said telecommunications equipment cabinet from said selected cabinet and plinth modules.

9. The method as recited in claim 8 wherein said telecommunications equipment cabinet includes shutters.

10. The method as recited in claim 8 wherein said telecommunications equipment cabinet contains hardware element supports having registration features.

11. The method as recited in claim 10 wherein said hardware element supports are spaced apart to allow both substantial longitudinal airflow and substantial lateral airflow.

12. The method as recited in claim 8 wherein said telecommunications equipment cabinet includes a heater.

13. The method as recited in claim 8 further comprising:
determining a configuration of at least one interface plate based on said interfaces required at said particular site; and
selecting said at least one interface plate from a plurality of selectable interface plates each having at least one interface aperture, said plurality of selectable interface plates further being part of said outdoor stackable telecommunications equipment cabinet family, said assembling said telecommunications equipment cabinet from said selected cabinet and plinth modules including assembling said telecommunications equipment cabinet from said at least one selected interface plate.

14. The method as recited in claim 8 wherein said telecommunications equipment is selected from the group consisting of:
power conversion/rectification equipment,
power distribution equipment,
digital baseband equipment,
radio frequency equipment;
Internet Protocol/router equipment, and
a backup battery.

15. An outdoor stackable telecommunications equipment cabinet family, comprising:
a plurality of selectable cabinet modules;
a plurality of selectable plinth modules; and
a plurality of selectable interface plates each having at least one interface aperture, at least one of said plurality of selectable cabinet modules and one of said plurality of selectable plinth modules configured to be selected and stacked and one of said plurality of selectable interface plates coupled to said one of said plurality of selectable plinth modules to form an outdoor telecommunications equipment cabinet that includes shutters, an air filter and at least one fan.

16. The family as recited in claim 15 wherein said telecommunications equipment cabinet contains hardware element supports having registration features.

17. The family as recited in claim 16 wherein said hardware element supports are spaced apart to allow both substantial longitudinal airflow and substantial lateral airflow.

18. The family as recited in claim 15 wherein said telecommunications equipment cabinet includes a heater.

19. The family as recited in claim 15 wherein said telecommunications equipment is selected from the group consisting of:
power conversion/rectification equipment,
power distribution equipment,
digital baseband equipment,
radio frequency equipment;
Internet Protocol/router equipment, and
a backup battery.

20. The family as recited in claim 15 wherein said shutters are configured to allow said cabinet to operate in a selectable one of:
a fully-ventilated mode of operation,
a partially-ventilated mode of operation, and
an internally-ventilated mode of operation.
